(19) United States
(12) Patent Application Publication
(10) Pub. No.: US 2005/0172897 A1
(43) Pub. Date: Aug. 11, 2005

(54) Barrier layer process and arrangement

(76) Inventor: Frank Jansen, San Jose, CA (US)

Correspondence Address: Ira Lee Zebrak;The BOC Group, Inc., Legal Services - Intellectual Property, 575 Mountain Ave., Murray Hill, NJ, 07974, US

(21) Appl. No.: 10/774,841

(22) Filed: Feb. 9, 2004

(51) Int. Cl. C23C 16/00

(52) U.S. Cl. 118/718

(57) ABSTRACT

A method an apparatus is described using atomic layer deposition to form a barrier layer onto a substrate. The coated substrate exhibits reduced permeation to oxygen and water vapor.

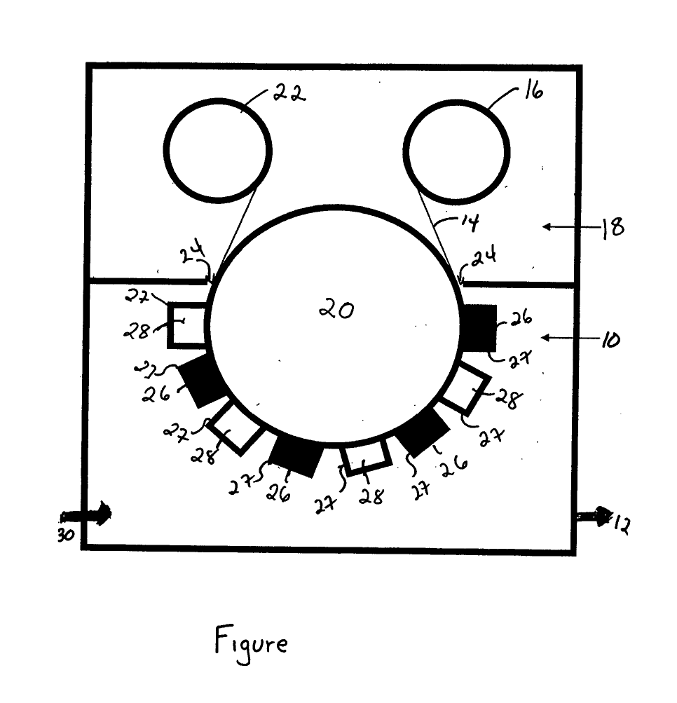

### BACKGROUND OF THE INVENTION

This invention is directed to an arrangement and process for creating barrier layers on a substrate which form a diffusion barrier for oxygen and water vapor. More particularly, this invention provides an arrangement and process in which barrier layers are formed on plastic substrates using atomic layer deposition. The resulting barrier layers will conform more closely to the substrate surface and reduce the occurrence of pinhole leaks and cracks.

Food and medical packaging often require low diffusion rates particularly for oxygen and water vapor. Sufficiently low rates of transmission of oxygen and water vapor are exhibited by glass packages such as glass jars, sealed glass vials, etc. Unfortunately glass based packaging is expensive. While polymer based packaging would be less costly, most polymer films with thicknesses useful in packaging application exhibit undesirably high permeability with respect to oxygen and water vapor. Lower gas permeation rates can be achieved by laminating plastic films formed from polymers with barrier materials.

A well known example of plastic film coated with a barrier material is aluminum coated polyethylene terephthalate (PET). Typically, this coated film material is used for the packaging of food products such as potato chips, peanuts, mini pretzels and the like. The aluminum-coated PET, while exhibiting good barrier properties as a result of the aluminum coating, is not optically transparent and is not compatible with microwave heating ovens.

Transparent barriers on plastic materials can be formed from alumina, or aluminum oxide and silica or silicon oxide as discussed in Chatham, Hood, Review: Oxygen diffusion barrier properties of transparent oxide coatings on polymeric substrates, Surface and Coatings Technology 78 (1996), pp 1-9. Typically, the silica and alumina are deposited on substrates as thin films, approximately 100-300 Å thick, by either thermal evaporation or by plasma-enhanced chemical vapor deposition (PECVD), for example, as disclosed in U.S. Pat. No. 5,224,441 which is incorporated by reference herein.

The preparation of thin film barriers on plastics presents several problems. The most significant problem is that polymers have rough surfaces and the films deposited by thermal evaporation or PECVD poorly conform to the undulation of the plastic substrate. For example, the typical average surface roughness of commercially available polyethylene terephthalate (PET) is 8-12 Å root mean square (rms), where 1 Å=10⁻¹⁰ m. The barrier performance that can be achieved is limited by the coverage of the surface plastic with the inorganic barrier material. At best, the permeability rate for 12 micron thick PET is decreased by about an order of magnitude for both oxygen and water vapor. While these permeability rates may be sufficient for certain packaging applications, other applications require much lower oxygen and water vapor permeability rates.

For example, much lower rates are required for plastic films used as substrates for microelectronic circuitry and displays. Organic light emitting diodes (OLEDs) include light emitting materials which rapidly degrade when exposed to minute quantities of oxygen and water vapor. OLED devices must be carefully sealed and protected from water vapor and oxygen. Further, any barrier material used to seal and protect the device from water and oxygen must be transparent to allow emission of light.

### SUMMARY OF THE INVENTION

It is an object of the invention to provide an atomic layer deposition arrangement and process to form a barrier layer for substrates which have reduced permeability to oxygen and water vapor.

Another object of the invention is to provide an atomic layer deposition arrangement and process which provides a barrier layer that closely conforms to a substrate surface.

A further object of the invention is to provide an atomic layer deposition arrangement and process which provides an optically transparent barrier layer for plastic substrates exhibiting a reduced amount of pinholes and cracks.

Those and other objects of the invention are achieved by an arrangement including an evacuatable chamber having at least two atomic layer deposition sources located in the chamber. Each atomic layer deposition source is isolated from the remainder of the chamber. A conveyor moves substrate through the evacuatable chamber. In this manner, the substrate is coated with barrier material and exhibits reduced permeability to oxygen and water vapor.

The invention also provides a method of forming a coated film comprising an atomic layer deposition arrangement comprising an evacuatable chamber having at least two atomic layer deposition sources, each source isolated from the remainder of the chamber. Substrate is conveyed to the first of the at least one atomic layer deposition source, exposing the substrate to the at least one atomic layer deposition source, and then conveyed to the next atomic layer deposition source where it is exposed to that next atomic layer deposition source. After exposing the substrate in this manner to a plurality of sources to form a sufficiently thick layer, such that the coated substrate exhibits reduced permeability to oxygen and water vapor, the coated substrate is conveyed out of the evacuatable chamber or removed from the chamber.

### BRIEF DESCRIPTION OF THE DRAWINGS

The attached FIGURE is a schematic representation of an atomic layer deposition arrangement in accordance with the invention.

### DETAILED DESCRIPTION OF THE PREFERRED EMBODIMENTS

In the present invention, a substrate is exposed to two or more atomic layer deposition sources such that a coating is formed on the substrate which provides a barrier to transmission of oxygen and water vapor across the substrate.

Atomic layer deposition is a method of depositing very thin films onto a surface. Individual precursor gases are pulsed onto the surface, typically a semiconductor wafer, in a sequential manner without mixing the precursors in the gas phase. Each precursor gas reacts with the surface to form an atomic layer in a way such that only one layer at a time can be deposited onto the surface.

An atomic layer deposition arrangement in accordance with the invention is shown in the attached FIGURE. The atomic layer deposition (“ALD”) arrangement includes a process chamber 10 which is evacuatable by processing pumps 12 (not shown). Substrate 14 is unwound from a supply roll 16 located in winding chamber 18. The substrate 14 is continuously fed into through and out of process chamber 10, routed over rotating temperature controlled processing drum 20 into processing chamber 10, and rewound on rewind drum 22 located in winding chamber 18. The radial speed of the three drums 16, 20 and 22 in relationship to each other and the tension forces in the substrate is actively controlled by the winding system. A suitable winding system is commercially available from Rockwell Automation in Mequon, Wis. and Eurotherm Inc. in Leesburg, Va. and can be used to move substrate 14 into, through and out of process chamber 10.

Fluid communication between winding chamber 18 and process chamber 10 is minimized by minimizing openings 24 between winding chamber 18 and process chamber 10. ALD sources 26 and 28 are arranged alternately (i.e. in alternating fashion) around process drum 20. Each ALD source 26, 28 is enclosed on all sides by a grounded shield 27 except for the side in close proximity to process drum 20. The ALD source itself is a linear gas manifold inlet system orientated parallel to the rotational axis of the drum. For those ALD processes requiring surface reactions with activated gases such as oxygen, hydrogen, nitrogen and fluorine, the ALD source from which this gas emerges may be electrical biased. An electrical bias exceeding several hundred volts will plasma-activate the gas into a chemically reactive state. These kinds of sources are well known and described, for example, in U.S. Pat. No. 5,627,435 which is incorporated herein by reference. Preferably the precursor gas is introduced into the ALD chamber 26 at a predetermined flow rate which is balanced by the leak rate of the gas from the shield 27 enclosed space into process chamber 10. Inert gas 30 flows into process chamber 10 to entrain the ALD precursor gases and move them along through the chamber exhaust system. The gas pressure in process chamber 10 is determined by the flow rate of inert gas 30 into chamber 10 and removal through pump 12 of inert gas and gas leaking from the ALD sources 26, 28. Typically, gas pressure in the chamber is less than 100 mtorr, more preferably less than 50 mtorr. The pressure in processing chamber 10 is maintained at a lower level than the pressure in the ALD sources by controlling the flow rate of inert gas 30 into the chamber and removal of gas by pump 12. The pressure of the precursor gas in the ALD sources 26, 28 is sufficiently high to cover the surface of substrate 14 as it travels over the open end of ALD source 26, 28. In this manner, the substrate 14 is alternatively exposed to gas A in ALD source 26, purge gas in process chamber 10, and gas B in ALD source 28 as it is conveyed through process chamber 10.

In addition, process conditions are arranged such that the monolayer A formed in ALD source 26 chemically reacts with monolayer B formed in ALD source 28. The chemical reaction may be induced by applying heat to processing drum 20.

The above is repeated, alternating gas discharge from ALD source 26 and ALD source 28 until the desired thickness of deposition layer is obtained. The thickness of the barrier layer according to the invention is 400 to 100 Å, preferably 200 Å to 50 Å, more preferably 150 Å to 50 Å thick.

Suitable substrates include but are not limited to flexible plastics. Preferred plastics include polymers selected from the group consisting of polyethylene terephthalate, polyacrylate, polypropylene, low density polyethylene, high density polyethylene, ethylene vinyl alcohol, polyphenylpropyleneoxide, polyvinyldene chloride and polyamides. The thickness of the substrate is typically from 10 μm to 1600 μm, preferably 10 μm to 50 μm. Precursors for making metallized transparent films in ALD are well known to those skilled in the art. Examples of commonly used precursors include O3, Al(CH3)3 and H2O, Al(CH3)3 and O2, Al(CH3)3 and nitrous oxide.

The invention will be further described by the following examples which are illustrative only and do not limit the invention.

### EXAMPLE

A PET substrate which is 12 micron thick is unwound from a roll into a drum in a process chamber. The drum in the process chamber is treated to 75° C. The PET substrate is exposed to a first ALD source which deposits trimethylaluminum and thereafter exposed to an ALD source of oxygen or nitrous oxide at process pressures of 100 mtorr. The PET substrate is repeatedly exposed sequentially to a source which deposits trimethylaluminum and thereafter to a source of oxygen or nitrous oxide. This can be achieved by exposing the substrate to the same sources by winding and unwinding substrate over the drum or by providing multiple sources. The film thickness corresponding to 100 passes over the ALD sources will be approximately 120 Å. Preferably, the coated substrate in accordance with the invention will have an oxygen permeability of less than 0.1 cc/m²/day, preferably less than 0.010 cc/m²/day, most preferably 0.001 cc/m²/day and transmission rate for water vapor less than 0.1 g/m²/day, preferably 0.01 g/m²/day, most preferably 0.001 g/m²/day.

Although preferred embodiments are specifically illustrated and described herein above, it will be appreciated that many modifications and variations of the present invention are possible in light of the above teachings and within the purview of the appended claims without departing from the spirit and intended scope of the invention.

1. Atomic layer deposition arrangement comprising:
an evacuatable chamber,
at least two atomic layer deposition sources within the chamber, wherein each atomic layer deposition source is isolated from the remainder of the chamber, and
means for conveying substrate through the evacuatable chamber.

2. Atomic layer deposition arrangement according to claim 1 wherein the means for conveying substrate comprises a rotatable drum.

3. Atomic layer deposition arrangement according to claim 1 further comprising a grounded shield for each atomic layer deposition source.

4. Atomic layer deposition arrangement according to claim 1 further comprising a substrate source chamber adjacent to the evacuatable chamber.

5. Atomic layer deposition arrangement according to claim 4 wherein the substrate source chamber comprises a first rotatable drum and a second rotatable drum, the first rotatable drum having polymer film wrapped around the drum, wherein the polymer film is conveyed into the evacuatable chamber, and the second rotatable drum receives the polymer film after the polymer film exits the evacuatable chamber.

6. Atomic layer deposition arrangement according to claim 5 wherein the polymer film comprises at least one selected from the group consisting of polyethylene terephthalate, polyacrylate, polypropylene, low density polyethylene, high density polyethylene, ethylene vinyl alcohol, polyphenylpropyleneoxide, polyvinyldene chloride and polyamides.

7. Atomic layer deposition arrangement according to claim 6 wherein the polymer film comprises polyethylene terephthalate.

8. Method for preparing a coated substrate comprising:
providing an atomic layer deposition arrangement comprising an evacuatable chamber, at least two atomic layer deposition sources within the chamber, wherein each atomic layer deposition source is isolated from the remainder of the chamber,
conveying substrate to the first of the at least one atomic layer deposition source,
exposing the substrate to the at least one atomic layer deposition source,
conveying the substrate to the next atomic layer deposition source, and
exposing the substrate to said next atomic layer deposition source.

9. Method for preparing a coated substrate according to claim 8 comprising conveying coated substrate out of the evacuatable chamber conveying substrate by rolling a rotatable drum which carries the substrate.

10. Method for preparing a coated substrate according to claim 9 comprising conveying substrate by rolling a rotatable drum which carries the substrate.

11. Method for preparing a coated substrate according to claim 8 wherein the substrate is a polymer film.

12. Method for preparing a coated substrate according to claim 11 wherein the polymer comprises at least one selected from the group consisting of: polyethylene terephthalate, low density polyethylene, high density polyethylene, polypropylene, polycarbonate, polyvinyldene chloride, ethylene vinyl alcohol, polyacrylate and polyamide.

13. Method for preparing a coated substrate according to claim 8 wherein the first atomic layer deposition source is a source of trimethylaluminum.

14. Method for preparing a coated substrate according to claim 13 wherein the oxidizing agent is selected from the group consisting of oxygen, nitrous oxide, and ozone.

15. Method for preparing a coated substrate according to claim 8 wherein the first atomic layer deposition source is a source of trimethylaluminum and the next atomic layer deposition source is a source of oxidizing agent.

16. Method for preparing a coated substrate according to claim 8 further comprising providing a substrate source chamber adjacent to the evacuatable chamber.

17. Method for forming a coated substrate according to claim 16 further comprising a first rotatable drum and a second rotatable drum in the substrate source chamber, the first rotatable drum having polymer film wrapped around the drum,
rotating the first rotatable drum and conveying polymer film into the evacuatable chamber, and
rotating the second rotatable drum and receiving polymer film exiting the evacuatable chamber.

18. Method for forming a coated substrated according to claim 8 further comprising introducing an inert gas into the evacuatable chamber.

19. Method for forming a coated substrate according to claim 8 wherein the inert gas is selected from the group consisting of argon and oxygen.

20. Method for forming a coated substrate according to claim 8 wherein the substrate is a polymer film and wherein a barrier coating which has a thickness of 400 Å to 50 Å is formed on the polymer film.
